(19) United States
(12) Patent Application Publication
(10) Pub. No.: US 2006/0046383 A1
(43) Pub. Date: Mar. 2, 2006

(54) Method for forming a nanocrystal floating gate for a flash memory device

(76) Inventors: Shenlin Chen, Boise, ID (US); Jeffrey B. Hull, Boise, ID (US)

Correspondence Address: Kevin D. Martin;Micron Technology, Inc., MS 1-525, 8000 S Federal Way, Boise, ID, 83716, US

(21) Appl. No.: 10/933,920

(22) Filed: Sep. 2, 2004

(51) Int. Cl. H01L 21/336

(52) U.S. Cl. 438/257

(57) ABSTRACT

One embodiment of a method used to form a floating gate for a memory device comprises forming a crystallization nucleus seed layer using a process comprising disilane (Si₂H₆), then converting the seed layer into a plurality of electrically-isolated silicon nanocrystals using a process comprising silane (SiH₄). The method described uses lower temperatures than previous silicon nanocrystal formation with improved uniformity of the completed silicon nanocrystals.

### FIELD OF THE INVENTION

This invention relates to the field of semiconductor manufacture and, more particularly, to a method for forming a flash memory device having a nanocrystal floating gate.

### BACKGROUND OF THE INVENTION

Floating gate memory devices such as flash memories, which are derivatives of electrically programmable read-only memories (PROMs) and electrically-erasable PROMs (EEPROMs), include an array of memory cells. Typically, each memory cell comprises a single n-channel metal oxide semiconductor (NMOS) transistor including a floating gate interposed between a control (input) gate and a channel. A layer of high-quality tunnel oxide used as gate oxide separates the transistor channel and the floating gate, and an oxide-nitride-oxide (ONO) dielectric stack separates the floating gate from the control gate. The ONO stack typically comprises a layer of silicon nitride (Si₃N₄) interposed between underlying and overlying layers of silicon dioxide (SiO₂). The underlying layer of SiO₂ is typically grown on the first doped polycrystalline silicon (polysilicon) layer. The nitride layer is deposited over the underlying oxide layer, and the overlying oxide layer can be either grown or deposited on the nitride layer. The ONO layer maximizes the capacitive coupling between the floating gate and the control gate and minimizes the leakage of current.

To program a flash cell, the drain region and the control gate are raised to predetermined potentials above a potential applied to the source region. For example, 12 volts are applied to the control gate, 0.0 volts are applied to the source, and 6.0 volts are applied to the drain. These voltages produce “hot electrons” which are accelerated from the substrate across the gate oxide layer to the floating gate. Various schemes are used to erase a flash cell. For example, a high positive potential such as 12 volts is applied to the source region, the control gate is grounded, and the drain is allowed to float. More common erase bias conditions include: a “negative gate erase” in which −10V is applied to the control gate (V_{g}), 6V is applied to the source (Vₛ), a potential of 0V is applied to the body (V_{body}), and the drain is allowed to float (V_{d}); and a “channel erase” which comprises a V_{g} of −9V, a V_{body} of 9V, and a Vₛ and V_{d} of 9V or floating. In each case these voltages are applied for a timed period, and the longer the period the more the cell becomes erased. A strong electric field develops between the floating gate and the source region, and negative charge is extracted from the floating gate across the tunnel oxide to the source region, for example by Fowler-Nordheim tunneling.

In a flash memory device, the sources associated with each transistor within a sector are tied together, typically through the use of conductive doping of the wafer to connect the sources of each transistor within a column. The columns within the sector are tied together using conductive plugs and a conductive line.

FIG. 1 depicts a cross section of transistors and other structures of a conventional flash electrically-erasable programmable read-only memory (E²PROM) device. FIG. 1 depicts the following structures: semiconductor substrate assembly comprising a semiconductor wafer 10, transistor source 12 and drain 14 diffusion regions within semiconductor wafer 10, gate (tunnel) oxide 16, floating gates 18 typically comprising a first polysilicon layer, capacitor dielectric 20 typically comprising an oxide-nitride-oxide (ONO) stack, control gate (word line) 22 typically comprising a second polysilicon layer, a transistor stack capping layer 24 typically comprising silicon nitride (Si₃N₄) or tetraethyl orthosilicate (TEOS), oxide or nitride spacers 26, a planar dielectric layer 28 such as borophosphosilicate glass (BPSG), digit line plugs 30 connected to drain regions 14, and a conductive line 32 typically comprising aluminum which electrically couples each plug 30 within a row of transistors. Conventional and inventive devices and methods are discussed in U.S. Pat. No. 6,624,024 by Prall which is assigned to Micron Technology, Inc. and incorporated herein as if set forth in its entirety.

Recent developments in flash memory device manufacturing include the formation of the floating gate from conductive silicon nanocrystals, referred to as “nanocrystalline silicon” or “nanosilicon.” For example, U.S. Pat. Nos. 5,754,477 and 5,852,306 by Forbes, each of which is assigned to Micron Technology, Inc. and incorporated herein by reference as if set forth in its entirety, describe the formation and use of a flash memory device having a nanosilicon floating gate.

Conventional processes for forming a flash memory device floating gate from conductive nanocrystals comprise the use of silane (SiH₄) to form a silicon seed layer, then using dichlorosilane (SiH₂Cl₂) to grow the nanocrystal using the seed layer for crystal formation. In one conventional process, silane is introduced into a deposition chamber at a temperature greater than 600° C. to form a silicon seed layer on a gate oxide layer. Next, dichlorosilane is introduced into the chamber at a temperature greater than 600° C. to form nanocrystals from the seed layer.

Nanocrystal floating gates are an improvement over conventional polysilicon floating gates for several reasons. For example, a distributed nanometer-scale storage medium has improved strength against stress-induced leakage current and, therefore, improved retention of the stored charge. Further, the number of program/erase cycles (i.e. “endurance”) of the cell is increased before the memory operation begins to fail. Additionally, if the tunnel oxide is defective only the crystal(s) near the defect will fail, and the remaining crystals which are electrically-isolated from the other crystals, and thus the memory cell itself, will maintain its functionality; in previous cells such a defect would result in loss of the entire charge of the cell due to the charge being stored on the floating gate, which is a single electrical feature.

Improving the uniformity of nanocrystals over conventional processing is a desirable design goal because uniform nanocrystals result in more uniform tunneling through the tunnel oxide, which results in uniform charging and discharging of the storage islands over the channel area. Thus the electrical properties of the memory cell can be more easily predicted with uniform nanocrystals and a cell having improved functionality is formed. More uniform nanocrystals, for purposes of this disclosure, are ones having a decreased distribution with respect to size or volume (or both) and/or which form at more evenly-spaced intervals.

Another design goal of semiconductor processing engineers is to decrease the temperatures required for processing semiconductor wafers. Conventional high-temperature processes such as that described above require processing at a temperature greater than 600° C. and are known to stress features on the semiconductor wafer, especially at locations where two or more different materials contact each other. Further, high processing temperatures cause dopants to migrate from their desired location thereby decreasing the doping density and possibly resulting in device leakage. Lowering a processing temperature at one step may allow a better but higher temperature process to be used at another step because lower temperature processing conserves the thermal budget allowable during processing. However, forming the seed layer at a lower temperature is not possible because silane cannot effectively seed on oxide at low temperature.

A method for forming conductive nanocrystals at a decreased temperature and with improved density and uniformity would be desirable.

### SUMMARY OF THE INVENTION

The present invention provides a new method which, among other advantages, allows formation of conductive nanocrystals, for example during the formation of a flash memory device floating gate, with improved uniformity, at a lower temperature, and with more controllability than is found with conventional processes.

Advantages will become apparent to those skilled in the art from the following detailed description read in conjunction with the appended claims and the drawings attached hereto.

### BRIEF DESCRIPTION OF THE DRAWINGS

FIG. 1 is a cross section depicting a conventional floating gate memory device;

FIGS. 2-7 are cross sections depicting various intermediate structures formed during one embodiment of the invention;

FIG. 8 is an isometric depiction of various components which may be manufactured using devices formed using an embodiment of the present invention; and

FIG. 9 is a block diagram of an exemplary use of the invention to form part of a transistor array in a memory device.

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE PREFERRED EMBODIMENT

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with layers including dielectrics and conductors, and features such as transistors, formed thereover, depending on the particular stage of processing. In addition, the semiconductor need not be silicon-based, but could be based on silicon-germanium, silicon-on-insulator, silicon-on-sapphire, germanium, or gallium arsenide, among others. Further, in the discussion and claims herein, the term “on” used with respect to two layers, one “on” the other, means at least some contact between the layers, while “over” means the layers are in close proximity, but possibly with one or more additional intervening layers such that contact is possible but not required. Neither “on” nor “over” implies any directionality as used herein.

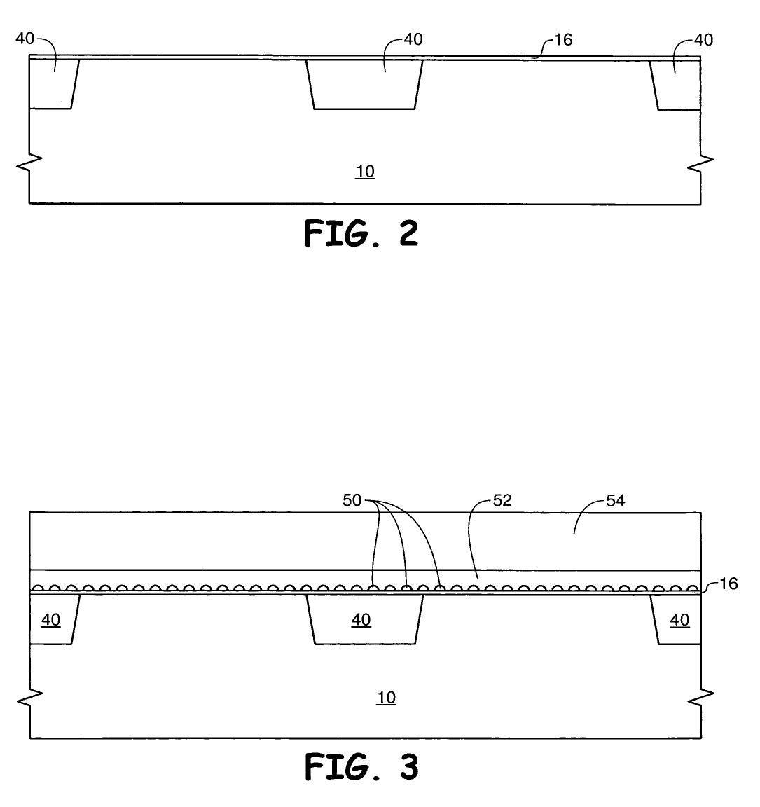

A first embodiment of an inventive method for forming a flash memory device having a nanocrystal floating gate is depicted in FIGS. 2-7. FIG. 2 depicts a semiconductor wafer 10 having a shallow trench isolation (STI) region 40 and a gate oxide layer 16 typically formed from high-quality tunnel oxide.

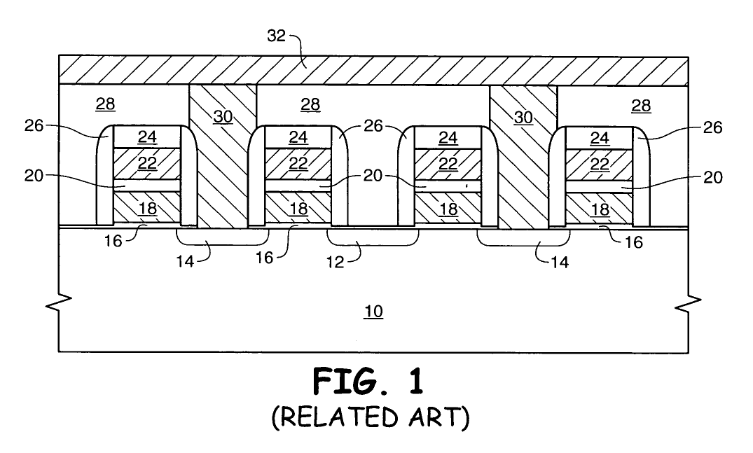

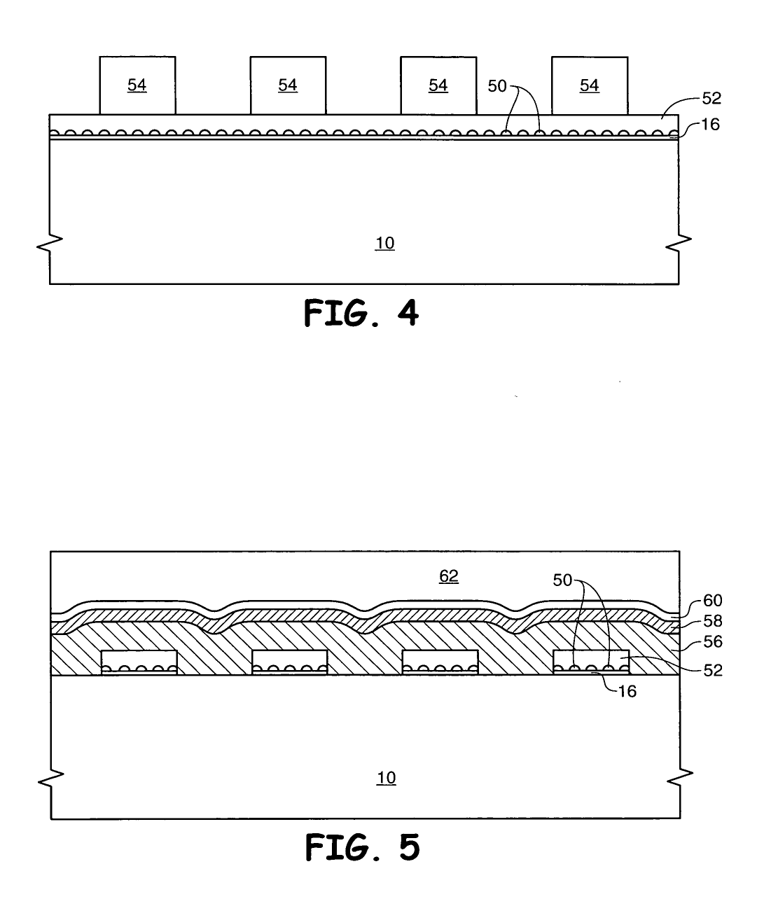

It should be noted that FIGS. 1-3, 6, and 7 are depicted in the row direction (i.e. in transverse section with regard to the control gate), the column direction being at right angles with the orientation of each of FIGS. 1-3, 6, and 7. FIGS. 4 and 5 are depicted in the column direction (i.e. in transverse section with regard to the digit line), the row direction being at right angles with the orientation of each of FIGS. 4 and 5.

After forming the FIG. 2 structure, which can easily be formed by one of ordinary skill in the art from the description herein, a nanocrystal layer 50 is formed on the tunnel oxide layer 16. The nanocrystal layer is formed using two basic steps, with the first step forming a crystalline seed layer and the second step forming nanocrystals which use the seed layer as a crystallization nucleus. To form the seed layer the wafer assembly of FIG. 2 is placed into a deposition chamber (or remains in a deposition chamber from a prior processing step) and disilane (Si₂H₆) is introduced into the chamber at a flow rate of between about 1 sccm and about 2,000 sccm, and more preferably at a flow rate of between about 10 sccm and about 500 sccm, and most preferably at a flow rate of between about 20 sccm and about 60 sccm. This process is performed at a pressure of between about 10 millitorr (mT) and about 200 mT, and more preferably at a pressure of between about 10 mT and about 100 mT, and a temperature of between about 350° C. and about 600° C., and more preferably between about 375° C. and about 500° C. Along with the disilane, gasses such as nitrogen, hydrogen, helium, and argon can be used for dilution of the disilane to appropriate concentrations. This will form a plurality of individual, physically-spaced seed layer portions. To form the crystallization nuclei closer together the deposition temperature may be increased. For example, at a flow rate of 15 sccm, a pressure of 30 mT, and a temperature of 475° C., the crystallization nuclei will form at an estimated mean distance of about 100 Å from each other. While this process is described for an ASM A400 furnace, any necessary adjustments to the flow rates, temperatures, pressures, etc. can be made by one of ordinary skill in the art. In one specific embodiment this first step is performed for a duration of between about 60 seconds and about 500 seconds to form a plurality of crystallization nuclei each less than about 10 Å thick and separated by a mean distance of about 100 Å. After the target layer is formed the chamber is purged.

To form the nanocrystals from the seed sites, silane (SiH₄) is introduced into the chamber at a flow rate of between about 10 sccm and about 500 sccm, and more preferably at a flow rate of between about 10 sccm and about 400 sccm, and most preferably at a flow rate of between about 15 sccm and about 200 sccm. The chamber pressure is maintained at between about 10 mT and about 500 mT, and more preferably between about 20 mT and about 200 mT, while the chamber temperature is maintained at between about 425° C. and about 525° C., for example at 450° C. This forms individual, physically-spaced nanocrystals at a rate of about 10 Å per minute, so for a nanocrystal floating gate layer of about 50 Å, with each nanocrystal spaced from adjacent nanocrystals at a mean distance of about 50 Å, the process is performed for between about 5 minutes and about 15 minutes to form the floating gate layer 50 of FIG. 3. This process of introducing disilane and then introducing silane may be repeated to form a thicker nanocrystal layer.

In contrast to conventional nanocrystal formation which uses silane to form a silicon seed and dichlorosilane to grow the seed into a nanocrystal, this embodiment of the invention uses disilane to form the silicon seed and silane to grow the seed into a nanocrystal. Further, conventional processes require a temperature greater than 600° C. to form the seed layer and greater than 600° C. to form the nanocrystal, while the present embodiment of the invention may form the seed at a lower temperature, for example about 425° C. and forms the nanocrystal at a temperature of about 500° C., which improves the thermal budget of device formation. Further, the grain size and density may be more easily controlled in this disclosed process than with conventional processes.

The plurality of nanocrystals may be formed so that each nanocrystal is electrically isolated from adjacent nanocrystals as depicted in FIG. 3, or a continuous layer of nanocrystals may be formed depending on the mean distance of the crystallization nuclei and the length of time the nanocrystal formation process is performed.

After forming the nanocrystal layer 50 of FIG. 3, a capacitor cell dielectric layer 52 and a patterned photoresist layer 54 are formed. The capacitor cell dielectric 52 can comprise a conventional oxide-nitride-oxide (ONO) structure. For nanocrystals 50 about 50 Å thick, a cell dielectric layer 52 between about 10 Å and about 100 Å would be sufficient. Photoresist layer 54 is patterned to form the first etch of the floating gate layer 50. FIG. 3 is a sectional view with photoresist layer 54 in longitudinal cross section, while FIG. 4 depicts the FIG. 3 structure but with photoresist layer 54 in transverse cross section (i.e. rotated 90° with respect to FIG. 3, as is well known in the art).

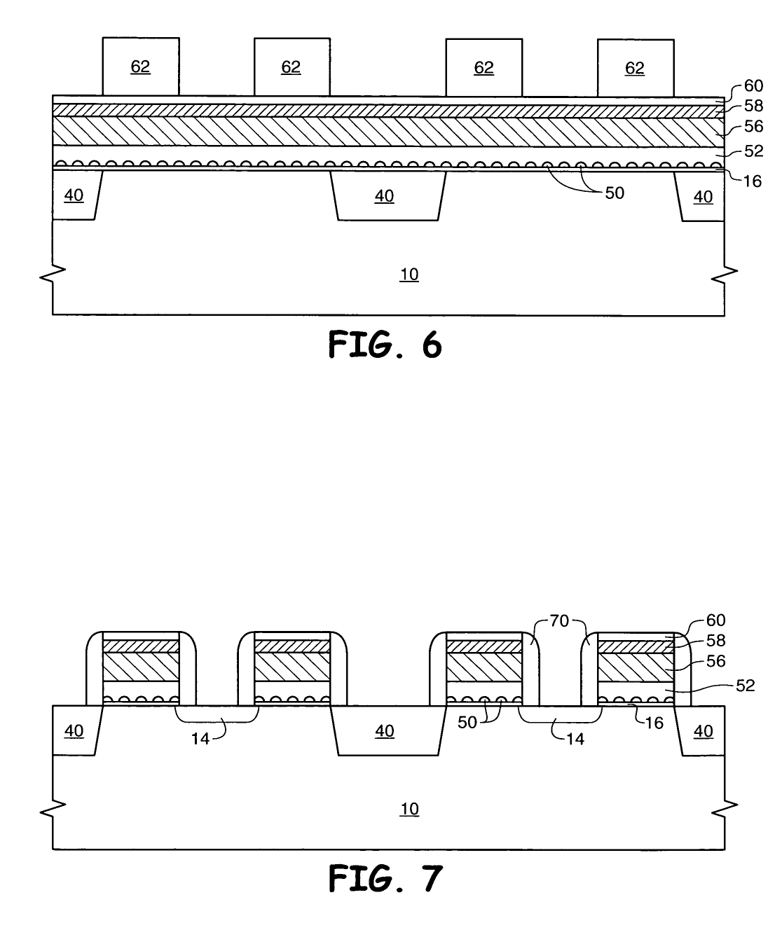

FIG. 5 depicts the FIG. 4 structure after etching the cell dielectric 52, the nanocrystal floating gate layer 30, and the tunnel oxide 16 using patterned resist layer 54. At this step the tunnel oxide may be only partially etched. Also at FIG. 5, photoresist layer 54 has been removed and polysilicon control gate layer 56, silicide layer 58, capping silicon nitride layer 60, and patterned photoresist layer 62 have been formed according to means known in the art. FIG. 5 is a cross section depicting photoresist layer 62 in longitudinal cross section, while FIG. 6 depicts the FIG. 5 structure with photoresist layer 62 in transverse cross section.

After forming the structure of FIGS. 5 and 6, an etch is performed according to means known in the art to pattern the capping layer 60, silicide layer 58, control gate layer 56, cell dielectric 52, floating gate layer 50, and gate oxide 16 to result in the patterned features of FIG. 7. FIG. 7 further depicts dielectric spacers 70 which have been formed subsequent to the removal of photoresist layer 62 according to means known in the art.

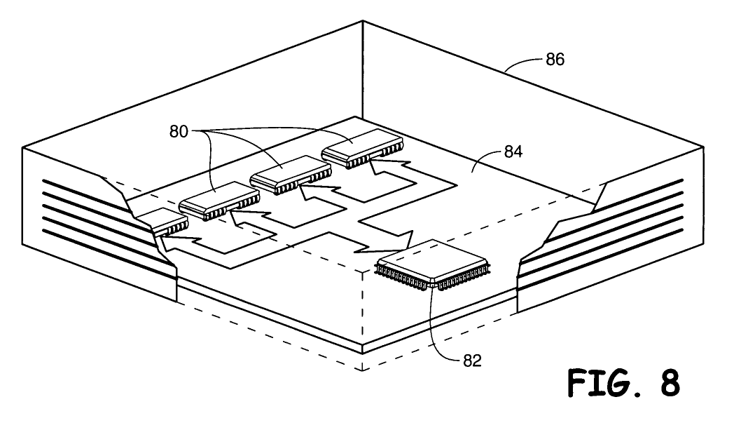

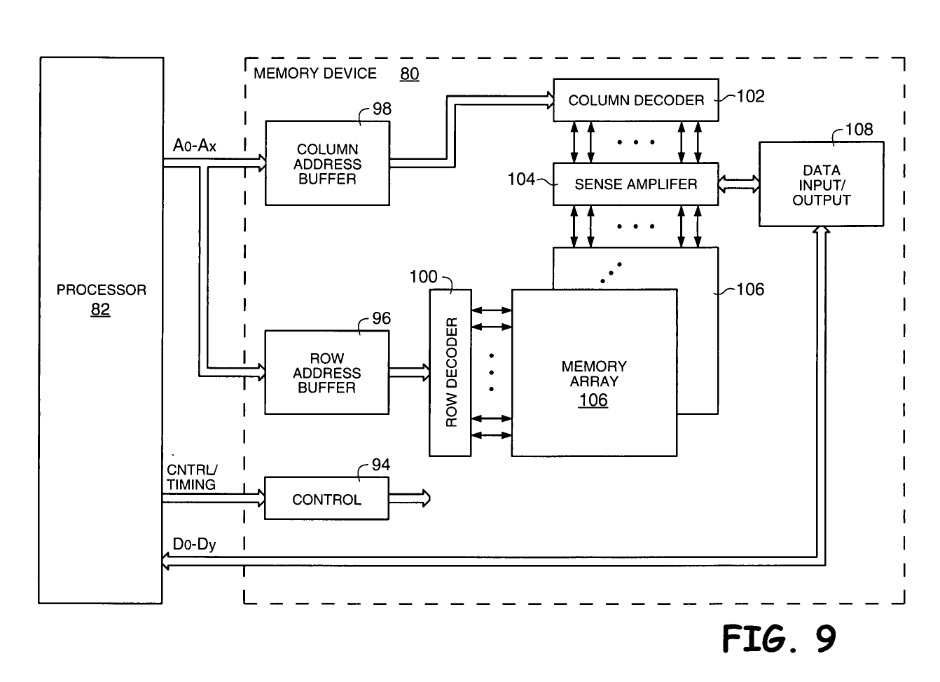

As depicted in FIG. 8, a semiconductor device 80 formed in accordance with the invention may be attached along with other devices such as a microprocessor 82 to a printed circuit board 84, for example to a computer motherboard or as a part of a memory module used in a personal computer, a minicomputer, or a mainframe 86. FIG. 8 may also represent use of device 80 in other electronic devices comprising a housing 86, for example devices comprising a microprocessor 82, related to telecommunications, the automobile industry, semiconductor test and manufacturing equipment, consumer electronics, or virtually any piece of consumer or industrial electronic equipment.

The process and structure described herein can be used to manufacture a number of different structures which comprise a structures. FIG. 9, for example, is a simplified block diagram of a memory device such as a flash memory having floating gates which may be formed using an embodiment of the present invention. The general operation of such a device is known to one skilled in the art. FIG. 9 depicts a processor 82 coupled to a memory device 80, and further depicts the following basic sections of a memory integrated circuit: control circuitry 94; row 96 and column 98 address buffers; row 100 and column 102 decoders; sense amplifiers 104; memory array 106; and data input/output 108.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. As described above, the nanocrystals may be physically and electrically separate, for they may be formed to provide a solid blanket layer prior the etch depicted between FIGS. 4 and 5. It is therefore contemplated that the appended claims will cover any such modifications or embodiments as fall within the true scope of the invention.

What is claimed is:

1. A method used to form a semiconductor device, comprising:
forming a semiconductor wafer substrate assembly comprising a semiconductor wafer;
placing the semiconductor wafer substrate assembly into a deposition chamber;
introducing disilane into the chamber to form a crystallization nucleus seed layer on the semiconductor wafer substrate assembly; and
introducing silane into the chamber to form a silicon nanocrystal layer from the crystallization nucleus seed layer.

2. The method of claim 1 further comprising introducing the disilane into the chamber at a flow rate of between about 1 standard cm³/minute (sccm) and about 2,000 sccm.

3. The method of claim 2 further comprising introducing the silane into the chamber at a flow rate of between about 10 sccm and about 500 sccm.

4. The method of claim 3 further comprising:
maintaining a chamber temperature of between about 350° C. and about 600° C. during the introduction of the disilane; and
maintaining a chamber temperature of between about 425° C. and about 525° C. during the introduction of the silane.

5. A method used to form a semiconductor device, comprising:
forming a tunnel oxide layer over a semiconductor wafer substrate assembly;
placing the semiconductor wafer substrate assembly into a deposition chamber;
introducing disilane into the deposition chamber at a flow rate of between about 1 sccm and about 2,000 sccm while maintaining a chamber pressure of between about 10 millitorr and about 200 millitorr and a chamber temperature of between about 350° C. and about 600° C. to form a seed layer on the tunnel oxide layer;
introducing silane into the deposition chamber at a flow rate of between about 10 sccm and about 500 sccm while maintaining a chamber pressure of between about 10 millitorr and about 500 millitorr and a chamber temperature of between about 425° C. and about 525° C. to form silicon nanocrystals from the seed layer.

6. The method of claim 5 further comprising:
forming a blanket capacitor cell dielectric layer over silicon nanocrystals;
forming a blanket conductive word line layer over the capacitor cell dielectric layer; and
etching the word line layer, the capacitor cell dielectric layer, and the nanocrystal layer to form a portion of a floating gate transistor.

7. A method used to form a semiconductor device, comprising:
forming a tunnel oxide layer over a semiconductor wafer substrate assembly;
in a deposition chamber, introducing disilane at a flow rate of between about 1 standard cm³/minute (sccm) and about 2,000 sccm to form a silicon seed layer comprising a plurality of individual, physically-spaced seed layer portions, with each seed layer portion having a diameter of less than about 10 angstroms (Å) in diameter;
in the deposition chamber, introducing silane at a flow rate of between about 15 sccm and about 200 sccm to convert the individual, physically-space seed layer portions into individual, physically-space nanocrystals each having a width of about 50 Å and spaced from adjacent nanocrystals at a mean distance of about 50 Å.

8. The method of claim 7 further comprising:
subsequent to introducing silane into the chamber, reintroducing disilane into the chamber to form a plurality of individual, physically-spaced seed layer portions; then
reintroducing silane into the chamber to convert the individual, physically-spaced seed layer portions into a plurality of nanocrystals.

9. The method of claim 7 wherein the reintroduction of disilane and the reintroduction of silane is repeated to form a continuous layer of nanocrystals on the tunnel oxide layer.

10. The method of claim 7 further comprising:
maintaining a chamber temperature of between about 375° C. and about 500° C. during the introduction of disilane into the chamber; and
maintaining a chamber temperature of between about 425° C. and about 425° C. during the introduction of silane into the chamber.
